(19) United States
(12) Patent Application Publication
(10) Pub. No.: US 2025/0019141 A1
(43) Pub. Date: Jan. 16, 2025

(54) PROBE CARD CARRIER

(71) Applicants: Dong Wook LEE, Seongnam-si (KR); BRIDGE CO., LTD., Seongnam-si (KR)

(72) Inventor: Dong Wook LEE, Seongnam-si (KR)

(73) Assignees: Dong Wook LEE, Seongnam-si (KR); BRIDGE CO., LTD., Seongnam-si (KR)

(21) Appl. No.: 18/467,084

(22) Filed: Sep. 14, 2023

(30) Foreign Application Priority Data
Jul. 14, 2023 (KR) 10-2023-0091601

(51) Int. Cl. B65D 81/05; B65D 85/30

(52) U.S. Cl. CPC B65D 81/05; B65D 85/30; H01L 21/67288

(57) ABSTRACT

The present disclosure relates to a probe card carrier. The probe card carrier of the present disclosure may include: a lower case; an upper case configured to cover the lower case; a seating module disposed in the lower case to allow a probe card to be seated thereon; and a card buffer portion installed in the seating module to elastically support a bottom surface and a circumference of the probe card.

### CROSS-REFERENCE TO RELATED APPLICATION(S)

This application claims benefit of priority to Korean Patent Application No. 10-2023-0091601, filed on Jul. 14, 2023, in the Korean Intellectual Property Office, the disclosures of which are incorporated herein by reference in their entirety.

### BACKGROUND

The present disclosure relates to a probe card carrier capable of suppressing the transmission of an impact to a probe card. In general, wafers are manufactured through semiconductor manufacturing processes. A probe card is used to electrically connect a tester to a chip on a wafer in the process of testing the wafer. The probe card has a structure of having a plurality of probe pins attached to a circuit board of a certain size. The probe card can be made in a variety of shapes to fit the arrangement of chips on the wafer to be tested and the arrangement of pads on the chips.

Inside a circuit board, hundreds of thousands to millions of vias are connected to dozens of internal layers. Since the circuit board requires rigidity capable of preventing deformation with respect to a load applied to the plurality of probe pins, a ceramic substrate is used as the circuit board.

A wafer is loaded onto a probe chuck. The probe pins are connected to pads (power connection portion) of the chip on the wafer. A signal sent from a tester is transmitted to the chip of the wafer through the probe card, and a signal output from the chip is transmitted back to the tester through the probe card. The tester determines whether the chip is defective based on the signal received from the chip.

Since the entire probe card is considered to be defective when there is a single power transmission failure, the yield of the probe card and impact protection during transportation are very important. These probe cards are very expensive products. Therefore, a carrier is transferred while the probe card is stably seated inside the carrier so that the probe card can be protected from external impacts or vibrations. Accordingly, a carrier capable of safely accommodating the probe card is requested.

The background art of the present disclosure is disclosed in the Korean Patent Publication No. 2016-0109748 (published on Sep. 21, 2016).

### SUMMARY OF THE INVENTION

Aspects of the present disclosure are to address at least the above-mentioned problems, and aim to provide a probe card carrier capable of suppressing the transmission of impact to a probe card.

An object of the present disclosure is to provide a probe card carrier in which a probe card may be supported with a minimum frictional force.

Technical problems of the present disclosure are not limited to the above-mentioned purposes, and other purposes and advantages of the present disclosure that are not mentioned may be understood by the following description, and will be more clearly understood by embodiments of the present disclosure. In addition, it will be easily seen that the objectives and advantages of the present disclosure can be realized by means indicated in the claims and combinations thereof.

To address the above problems, a probe card carrier according to the present disclosure may include: a lower case; an upper case configured to cover the lower case; a seating module disposed in the lower case to allow a probe card to be seated thereon; and a card buffer portion installed in the seating module to elastically support a bottom surface and a circumference of the probe card.

The card buffer portion may include a plurality of lower elastic balls disposed in the seating module to elastically support the bottom surface of the probe card; and a plurality of circumferential elastic balls disposed in the seating module to elastically support the circumference of the probe card.

The plurality of lower elastic balls may be arranged in the seating module along a circumferential direction.

The plurality of circumferential elastic balls may be arranged concentrically with the lower elastic balls on the outside of the plurality of lower elastic balls.

The seating module may include a plurality of seating blocks arranged along the circumferential direction in the lower case, and in which the lower elastic ball and the circumferential elastic ball are arranged.

The seating block may include, a seating plate positioned and fixed to the lower case; a lower supporter protruding upwardly from the seating plate and having a lower seating groove formed in a hemispherical shape to accommodate a bottom side of the lower elastic ball; a circumferential supporter protruding higher than the lower supporter on the outside of the lower supporter and having a circumferential seating groove formed to allow the circumferential elastic ball to protrude toward the lower supporter and to be seated; and a circumferential bracket having a bracket groove formed to surround an upper side of the circumferential elastic ball, and coupled to an upper side of the circumferential supporter.

The seating block may be installed to be repositionable in the lower case according to a size or shape of the probe card.

An accommodation space surrounded by the circumferential seating groove and the bracket groove may be formed in a hemispherical shape.

The accommodation space may be formed to be larger than half of the circumferential elastic ball to prevent the circumferential elastic ball from falling out of the accommodation space.

A coupling protrusion may be formed on the lower elastic ball, and a lower coupling hole may be formed in the lower seating groove to allow the coupling protrusion to be inserted and restrained.

The probe card carrier may further include: a plurality of upper blocks coupled to the upper case and formed with upper seating grooves; and a plurality of upper elastic balls coupled to the plurality of upper seating grooves to elastically support a top surface of the probe card.

A fastening protrusion may be formed on the upper elastic ball, and an upper fastening hole may be formed in the upper seating groove to be inserted and restrained the fastening protrusion.

A through-hole portion may be formed on the upper case, and the probe card carrier may further include, a window portion installed to close the through-hole portion; and an upper sealing portion interposed between a circumference of the through-hole portion and a circumference of the window portion.

The probe card carrier may further include a sealing member installed to seal a circumference of the lower case and the upper case.

The probe card carrier may further include a vacuum valve installed in the upper case.

The probe card carrier may further include a plurality of external buffer portions coupled to the circumference of the lower case and the upper case.

According to the present disclosure, since the card buffer portion elastically supports the bottom surface and the circumference of the probe card, it is possible to prevent the probe card from being damaged or destroyed by vibrations in the vertical and horizontal directions during transportation.

According to the present disclosure, since the spherical lower elastic balls support the bottom surface of the probe card, the upward and downward vibration or impact of the probe card carrier may be evenly dispersed in all directions from the lower elastic balls.

According to the present disclosure, since the lower elastic balls made of an elastic material are in point contact with the bottom surface of the probe card, the plurality of lower elastic balls may maintain a minimum friction area with the probe card, thereby significantly reducing the possibility of damage caused by frictional force.

According to the present disclosure, when some of the lower elastic balls have a slight height deviation from the other lower elastic balls, the amount of shrinkage of the lower elastic balls is slightly changed, and thus the probe card may be maintained in a horizontal state.

According to the present disclosure, since the spherical circumferential elastic balls support the circumference of the probe card, the horizontal vibration or impact of the probe card carrier may be evenly dispersed in all directions from the circumferential elastic balls.

According to the present disclosure, when some of the circumferential elastic balls are slightly deviated in the radial direction of the circumference, the amount of shrinkage of the circumferential elastic balls is slightly changed, and thus the circumference of the probe card may be stably elastically supported.

According to the present disclosure, the deviation to the radial direction of the plurality of circumferential elastic balls may be corrected by the deviation of the shrinkage amount of the circumferential elastic balls.

### BRIEF DESCRIPTION OF THE DRAWINGS

FIG. 1 is a perspective view schematically illustrating a probe card carrier according to the present disclosure;

FIG. 2 is a perspective view schematically illustrating a state in which an upper case is opened in the probe card carrier according to the present disclosure;

FIG. 3 is a perspective view schematically illustrating a state in which a probe card is seated in a lower case according to the present disclosure;

FIG. 4 is an exploded perspective view schematically illustrating the probe card carrier according to the present disclosure;

FIG. 5 is a cross-sectional view schematically illustrating a state in which the upper case is opened in the probe card carrier according to the present disclosure;

FIG. 6 is a cross-sectional view schematically illustrating a state in which the probe card is elastically supported by a card buffer portion in the probe card carrier according to the present disclosure;

FIG. 7 is an enlarged cross-sectional view schematically illustrating a state in which the probe card is elastically supported by the card buffer portion in the probe card carrier according to the present disclosure;

FIG. 8 is an enlarged cross-sectional view schematically illustrating a state in which a position of a seating module is changed according to the present disclosure;

FIG. 9 is a perspective view schematically illustrating a state in which the card buffer portion according to the present disclosure is installed in the seating module;

FIG. 10 is an exploded perspective view schematically illustrating the card buffer portion and the seating module according to the present disclosure;

FIG. 11 is a cross-sectional view schematically illustrating the card buffer portion and the seating module according to the present disclosure;

FIG. 12 is a perspective view schematically illustrating an upper pusher according to the present disclosure;

FIG. 13 is an exploded perspective view schematically illustrating the upper pusher according to the present disclosure; and

FIG. 14 is a cross-sectional view schematically illustrating the upper pusher according to the present disclosure.

### DETAILED DESCRIPTION OF EXEMPLARY EMBODIMENTS

The present disclosure is not limited to the embodiments disclosed herein, but may be subject to various modifications and implemented in many different forms. Embodiments of the present disclosure are provided so that the disclosure will be thorough and complete and will fully convey the scope of the present disclosure to those of ordinary skill in the art. Accordingly, the present disclosure is not limited to the embodiments disclosed herein, but is to be understood to include substitutions or additions of configurations of one embodiment for those of another, as well as all modifications, equivalents, or substitutions within the technical idea and scope of the present disclosure.

The accompanying drawings are intended to facilitate understanding of the embodiments disclosed herein, but the technical spirit disclosed herein is not limited by the accompanying drawings and should be understood to include all modifications, equivalents, or substitutions that are within the spirit and scope of the present disclosure. In the drawings, components may be shown exaggeratedly large or small in size or thickness for ease of understanding, but this shall not be construed to limit the scope of protection of the present disclosure.

Hereinafter, a probe card carrier according to an embodiment of the present disclosure will be described.

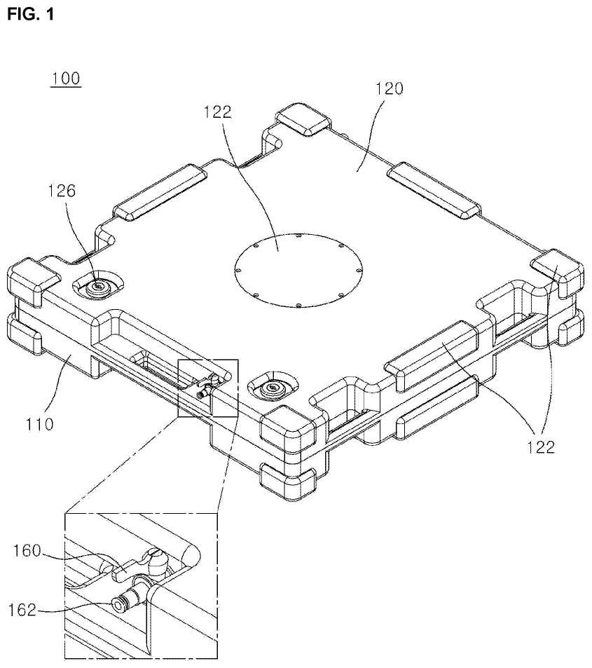

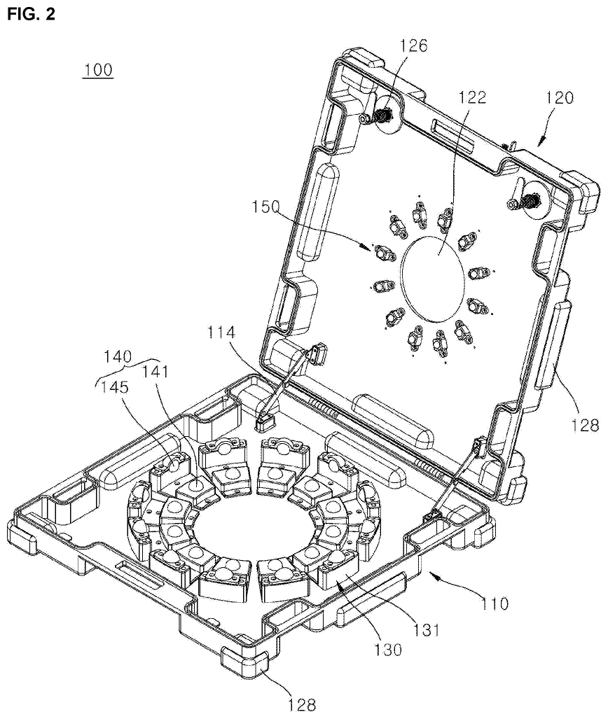

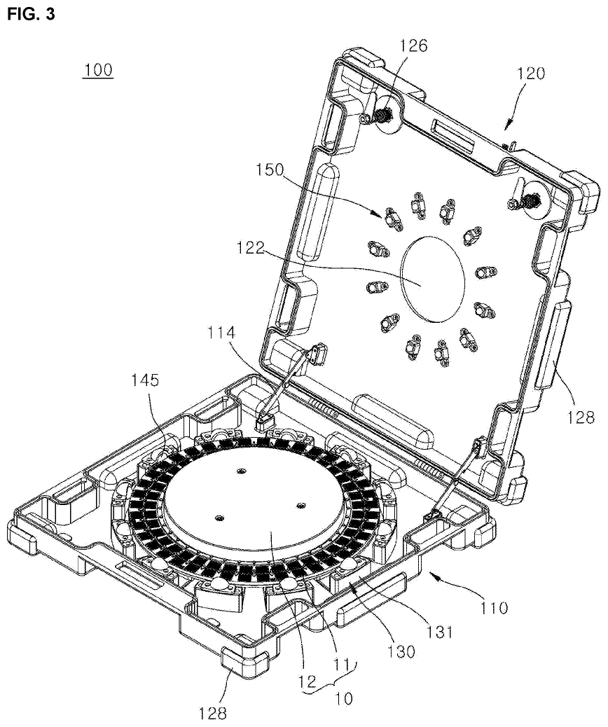

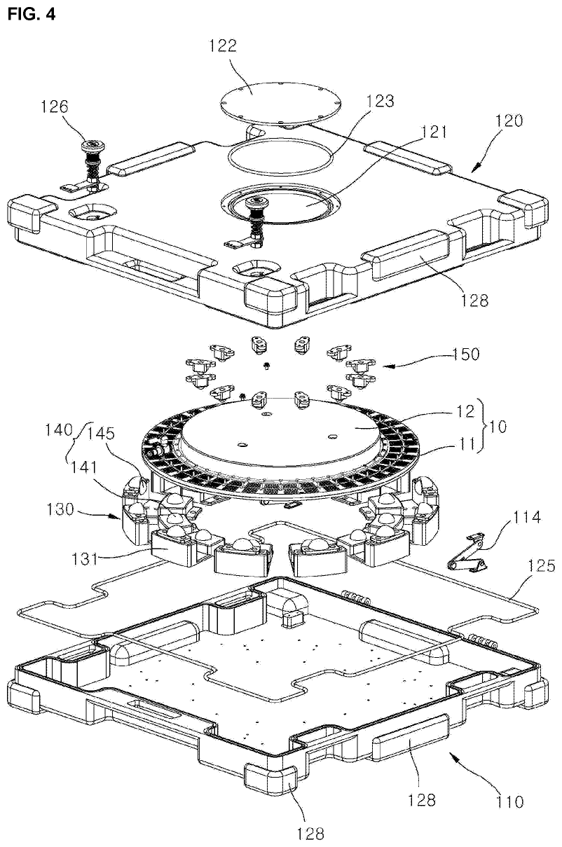

FIG. 1 is a perspective view schematically illustrating a probe card carrier according to the present disclosure, FIG. 2 is a perspective view schematically illustrating a state in which an upper case is opened in the probe card carrier according to the present disclosure, FIG. 3 is a perspective view schematically illustrating a state in which a probe card is seated in a lower case according to the present disclosure, and FIG. 4 is an exploded perspective view schematically illustrating the probe card carrier according to the present disclosure.

Referring to FIGS. 1 to 4, a probe card carrier 100 according to an embodiment of the present disclosure includes a lower case 110, an upper case 120, a seating module 130, and a card buffer portion 140.

The lower case 110 may be formed in a rectangular shape with an open upper portion. The lower case 110 may be formed of a synthetic resin material. This lower case may be manufactured in various forms.

The upper case 120 is formed in a size and shape corresponding to the lower case 110 to cover the upper side of the lower case 110. The upper case 120 may be formed of a synthetic resin material.

The seating module 130 is disposed in the lower case 110 so that a probe card 10 is seated thereon. For example, the seating module 130 may be fixed to the lower case 110 by a bolt, a rivet, an adhesive, etc. The seating module 130 may be formed in an integral annular shape or may be arranged in an annular shape by a plurality of block shapes. Of course, the seating module 130 may be manufactured in various forms as long as it stably supports the probe card 10.

The probe card 10 may include a ceramic substrate 11 and a circuit board 12. A plurality of probe pins (not shown) are disposed in the ceramic substrate 11. The plurality of probe pins are elastic so as not to damage the chips on the wafer. The ceramic substrate 11 is formed to have a strength capable of preventing deformation when the plurality of probe pins are in close contact with the pad of the wafer. The circuit board 12 is disposed on the upper side of the ceramic substrate 11. The circuit board 12 includes dozens or more layers of circuit patterns to be electrically connected to the probe pins (not shown). The circuit board 12 serves to electrically connect the plurality of probe pins and a tester.

The card buffer portion 140 is installed in the seating module 130 to elastically support a bottom surface and a circumference of the probe card 10. The card buffer portion 140 protects the probe card 10 by absorbing and dispersing external impact or vibration. Since the card buffer portion 140 elastically supports the bottom surface and the circumference of the probe card 10, it is possible to prevent the probe card 10 from being damaged or destroyed by vibrations in the vertical and horizontal directions during transportation.

A through-hole portion 121 may be formed in the upper case 120. In this case, a window portion 122 is installed to close the through-hole portion 121. An upper sealing portion 123 is interposed between a circumference of the through-hole portion 121 and a circumference of the window portion 122. The upper sealing portion 123 is formed in a shape corresponding to the shape of the window portion 122 and the through-hole portion 121. The upper sealing portion 123 seals a gap between the through-hole portion 121 and the window portion 122. Since the window portion 122 is installed in the upper case 120, the inside of the probe card carrier 100 may be visually checked from the outside.

The probe card carrier 100 further includes a sealing member 125 installed to seal the circumference of the lower case 110 and the upper case 120. The sealing member 125 is formed to correspond to the shape of the lower case 110 and the upper case 120. The sealing member 125 may be formed of elastic materials such as rubber, silicone, and urethane.

A key locker 126 is installed to lock the lower case 110 and the upper case 120. As the key locker 126 is rotated, the key locker 126 is restrained by a locking portion (not shown) of the lower case 110 so that the upper case 120 does not open. Various types of the key rocker 126 may be applied.

The probe card carrier 100 may further include a plurality of external buffer portions 128 coupled to circumferences of the lower case 110 and the upper case 120. The external buffer portion 128 may be formed of elastic materials such as rubber, silicone, and urethane. Approximately ten or more of the external buffer portions 128 may be installed around the corners and circumferential portions of the lower case 110 and the upper case 120. These external buffer portions 128 absorb impacts applied from the outside during transportation and loading of the probe card carrier 100.

The probe card carrier 100 may further include a vacuum valve 160 installed in the upper case 120. In this case, a vacuum port 162 connecting with an inner space is connected to the upper case 120, and the vacuum valve 160 is installed in the vacuum port 162. The probe card 10 is seated inside the upper case 120 and the lower case 110, the upper case 120 is closed to the lower case 110, and the key locker 126 locks the upper case 120 to the lower case 110. And, when a vacuum device (not shown) is connected to the vacuum port 162 and then vacuums the inner space of the upper case 120 and the lower case 110, the vacuum valve 160 may be manually operated to close the vacuum port 162. Accordingly, while the probe card carrier 100 is moved, the inner space of the upper case 120 and the lower case 110 may be maintained in a vacuum state.

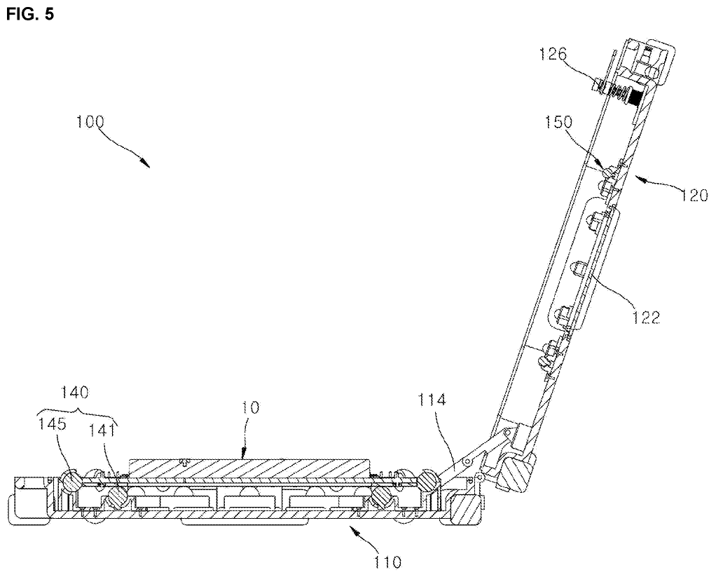

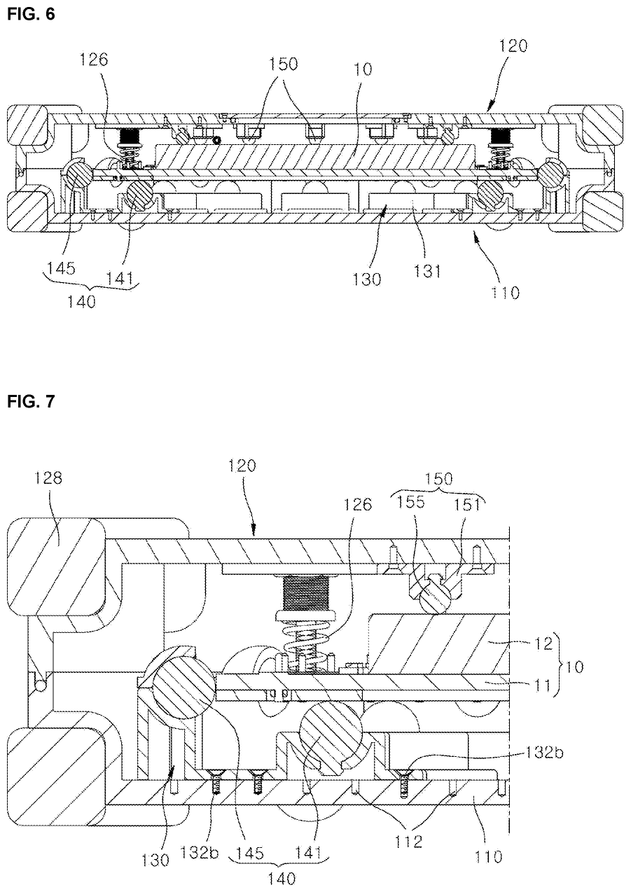

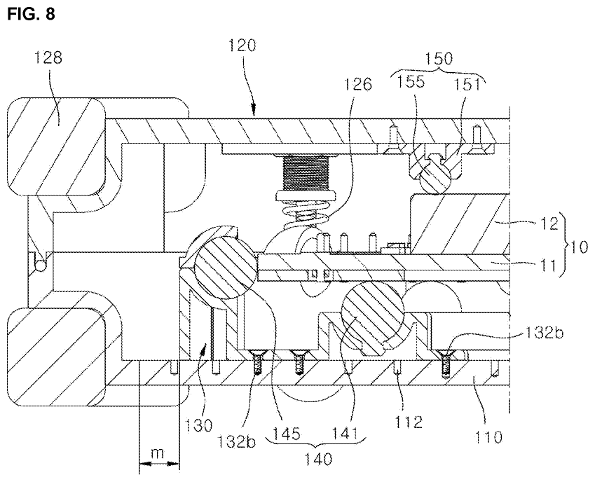

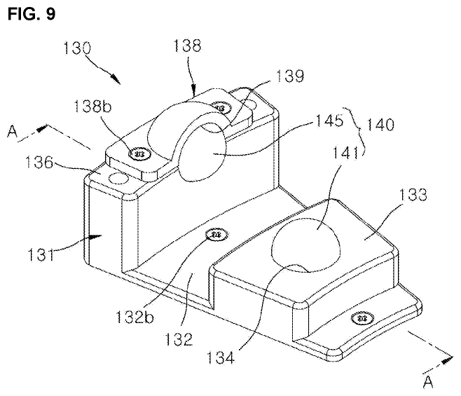

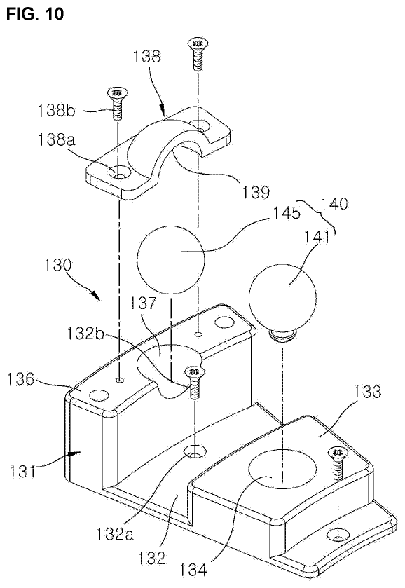

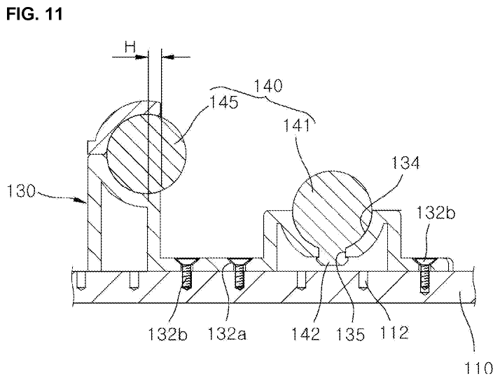

FIG. 5 is a cross-sectional view schematically illustrating a state in which the upper case is opened in the probe card carrier according to the present disclosure, FIG. 6 is a cross-sectional view schematically illustrating a state in which the probe card is elastically supported by a card buffer portion in the probe card carrier according to the present disclosure, FIG. 7 is an enlarged cross-sectional view schematically illustrating a state in which the probe card is elastically supported by the card buffer portion in the probe card carrier according to the present disclosure, FIG. 8 is an enlarged cross-sectional view schematically illustrating a state in which a position of a seating module is changed according to the present disclosure, FIG. 9 is a perspective view schematically illustrating a state in which the card buffer portion according to the present disclosure is installed in the seating module, FIG. 10 is an exploded perspective view schematically illustrating the card buffer portion and the seating module according to the present disclosure, and FIG. 11 is a cross-sectional view schematically illustrating the card buffer portion and the seating module according to the present disclosure.

Referring to FIGS. 5 to 11, the card buffer portion 140 includes a plurality of lower elastic balls 141 and a plurality of circumferential elastic balls 145.

The plurality of lower elastic balls 141 are disposed in the seating module 130 to elastically support a bottom surface of the probe card 10. The lower elastic balls 141 may be formed of elastic silicone materials or urethane materials. The plurality of lower elastic balls 141 are disposed on the outside of the circuit board 12 of the probe card 10 to avoid a plurality of probe pins. For example, the plurality of lower elastic balls 141 may be arranged in the seating module 130 along the circumferential direction. In this case, the plurality of lower elastic balls 141 may be disposed on one circumference at a central portion of the lower case 110. In addition, the plurality of lower elastic balls 141 may be disposed on at least two circumferences forming a concentric circle in the central portion of the lower case 110. This arrangement structure of the plurality of lower elastic balls 141 may be variously changed according to the size and shape of the probe card 10.

Since the spherical lower elastic balls 141 support the bottom surface of the probe card 10, upward and downward vibrations or impacts of the probe card carrier 100 may be evenly dispersed in all directions from the lower elastic balls 141. In addition, since the lower elastic ball 141 is formed in a spherical shape, the height of the lower elastic ball 141 or the supporting position of the probe card 10 is not changed even when the lower elastic ball 141 is seated in the seating module 130 in any direction.

In addition, since the lower elastic balls 141 made of elastic materials are in point contact with the bottom surface of the probe card 10, the plurality of lower elastic balls 141 may maintain a minimal friction area with the probe card 10, thereby significantly reducing the possibility of damage caused by frictional force. In addition, when some of the lower elastic balls 141 have a slight height deviation from the other lower elastic balls 141, the amount of shrinkage of the lower elastic balls 141 may be slightly changed, and thus the probe card 10 may be maintained in a horizontal state. Furthermore, the height deviation of the lower elastic balls 141 may be corrected by the deviation in the amount of shrinkage.

The plurality of circumferential elastic balls 145 may be disposed in the seating module 130 to elastically support the circumference of the probe card 10. The circumferential elastic balls 145 may be formed of elastic silicone materials or urethane materials. For example, the plurality of circumferential elastic balls 145 may be arranged concentrically with the lower elastic balls 141 on the outside of the plurality of lower elastic balls 141. The plurality of circumferential elastic balls 145 elastically support the outer circumferential surface of the ceramic substrate 11 of the probe card 10. The circumferential elastic balls 145 may be formed to have the same size as or different size from the lower elastic balls 141.

Since the spherical circumferential elastic balls 145 support the circumference of the probe card 10, horizontal vibration or impact of the probe card carrier 100 may be evenly dispersed in all directions from the circumferential elastic balls 145. In addition, since the circumferential elastic ball 145 is formed in a spherical shape, the supporting position of the probe card 10 is not changed even when the circumferential elastic ball 145 is seated in the seating module 130 in any direction.

In addition, since the circumferential elastic balls 145 made of elastic materials are in point contact with the circumference of the probe card 10, the plurality of circumferential elastic balls 145 may maintain a minimal friction area with the circumference of the probe card 10, thereby significantly reducing the possibility of damage caused by frictional force. In addition, when some of the circumferential elastic balls 145 are slightly deviated in the radial direction of the circumference, the circumference of the probe card 10 may be stably elastically supported as the amount of shrinkage of the circumferential elastic balls 145 is slightly changed. Furthermore, the radial deviation of the plurality of circumferential elastic balls 145 may be corrected by the shrinkage amount deviation of the circumferential elastic ball 145.

The seating module 130 includes a plurality of seating blocks 131 disposed in the lower case 110 along the circumferential direction, in which the lower elastic balls 141 and the circumferential elastic balls 145 are disposed. One lower elastic ball 141 and one circumferential elastic ball 145 may be disposed in each seating block 131. The plurality of seating blocks 131 may be disposed at equal intervals along the circumferential direction.

The seating block 131 may be installed to be repositionable in the lower case 110 according to the size of the probe card 10 (see FIGS. 7 and 8). For example, a plurality of insert nuts 112 may be radially insert-injected into the lower case 110, and a fixing bolt 132b of the seating block 131 may be coupled to the insert nut 112 after the seating block 131 is repositioned to fit the size of the probe card 10. Accordingly, various sizes of the probe cards 10 may be seated on the probe card carrier 100. In addition, the probe card carrier 100 does not need to be manufactured to fit various sizes of the probe cards 10. Furthermore, since the plurality of seating blocks 131 may be fixed at different positions in the radial direction of the circumference, the fixed positions of the seating blocks 131 may be changed to match the circumferential shape of the probe card 10. The structure in which the seating block 131 may be repositioned may be variously changed, such as a rail structure and a sliding structure.

The seating block 131 includes a seating plate 132, a lower supporter 133, a circumferential supporter 136, and a circumferential bracket 138.

The seating plate 132 is positioned and fixed to the lower case 110. At least two or more seating holes 132a are formed in the seating plate 132. The seating holes 132a are formed at an interval corresponding to an interval of the insert nuts 112. The fixing bolt 132b passes through the seating hole 132a and is coupled to the insert nut 112. The bottom side of the insert nut 112 has a structure that is blocked by the lower case 110.

The lower supporter 133 protrudes upward from the seating plate 132, and a lower seating groove 134 is formed in a hemispherical shape to accommodate the bottom side of the lower elastic ball 141. About half of the lower elastic ball 141 protrudes upward from the lower supporter 133. The radius of the lower seating groove 134 may be formed to be almost the same as the radius of the lower elastic ball 141. Accordingly, the lower elastic ball 141 may be stably accommodated in a state of protruding from the lower seating groove 134.

The circumferential supporter 136 may protrude higher than the lower supporter 133 on the outside the lower supporter 133, and a circumferential seating groove 137 may be formed such that the circumferential elastic ball 145 is seated to protrude toward the lower supporter 133. The circumferential elastic ball 145 is installed higher than the lower elastic ball 141. Since the circumferential elastic ball 145 protrudes toward the lower supporter 133, the circumference of the probe card 10 may be prevented from contacting the circumferential supporter 136.

The circumferential bracket 138 may have a bracket groove 139 formed to surround an upper side of the circumferential elastic ball 145, and may be coupled to an upper side of the circumferential supporter 136. The bracket groove 139 may be formed in a spherical surface about ¼ times that of the circumferential elastic ball 145. The bracket groove 139 is formed on both sides of the circumferential bracket 138, and a bracket bolt 138b is coupled to the bracket groove 139 and the circumferential supporter 136. A bracket hole 138a is formed on both sides of the circumferential bracket 138 to allow the bracket bolt 138b to pass therethrough. The circumferential bracket 138 may also be adhered to the top side of the circumferential supporter 136 by an adhesive. Accordingly, since the circumferential bracket 138 restrains the circumferential elastic ball 145, it is possible to prevent the circumferential elastic ball 145 from falling out of the circumferential seating groove 137 and the bracket groove 139.

An accommodation space surrounded by the circumferential seating groove 137 and the bracket groove 139 may be formed in a hemispherical shape. Accordingly, the circumferential elastic ball 145 may be seated in the accommodation space without being deformed.

The accommodation space may be formed to be larger than half of the circumferential elastic ball 145 to prevent the circumferential elastic ball 145 from falling out of the accommodation space (see FIG. 11). For example, when the circumferential elastic ball 145 is seated in the accommodation space, the inner end portion of the accommodation space has a structure extending a predetermined length H inward from the vertical diameter of the circumferential elastic ball 145. In this case, since more than half portion of the circumferential elastic ball 145 is inserted between the circumferential seating groove 137 and the bracket groove 139, it is possible to prevent the circumferential elastic ball 145 from falling out of the accommodation space.

A coupling protrusion 142 may be formed in the lower elastic ball 141, and a lower coupling hole 135 may be formed in the lower seating groove 134 such that the coupling protrusion 142 is inserted and restrained. A locking protrusion (not shown) larger than the lower coupling hole 135 is formed at an end portion of the coupling protrusion 142. Accordingly, it is possible to prevent the lower elastic ball 141 from falling out of the lower seating groove 134.

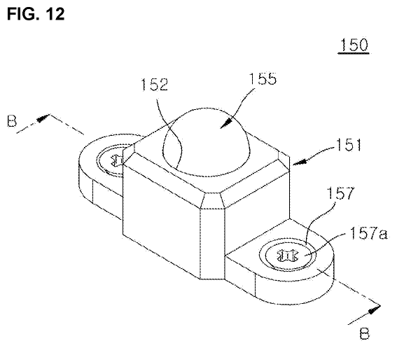

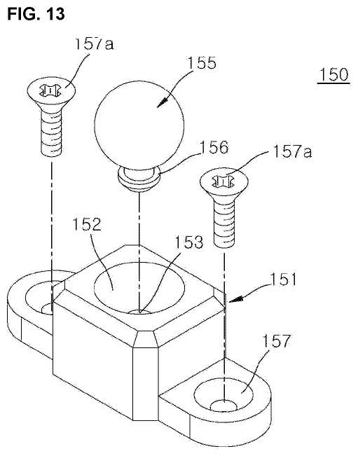

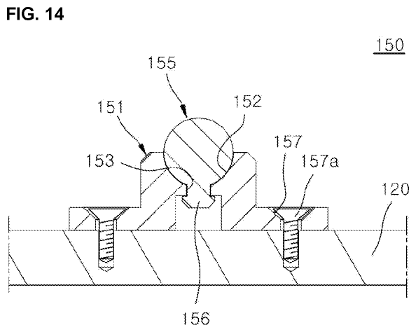

FIG. 12 is a perspective view schematically illustrating an upper pusher according to the present disclosure, FIG. 13 is an exploded perspective view schematically illustrating the upper pusher according to the present disclosure, and FIG. 14 is a cross-sectional view schematically illustrating the upper pusher according to the present disclosure.

Referring to FIGS. 12 to 14, the probe card carrier 100 may further include a plurality of upper blocks 151 and a plurality of upper elastic balls 155.

The plurality of upper blocks 151 are coupled to the upper case 120, and upper seating grooves 152 are formed. Upper fastening holes 153 may be formed on both sides of the upper block 151. In this case, an insert nut (not shown) is insert-injected into the upper case 120 to correspond to the upper fastening hole 153, and the upper block 151 is coupled to the upper case 120 as an upper bolt 157a is coupled to the insert nut through a bolt insertion hole 157.

The plurality of upper elastic balls 155 are coupled to the plurality of upper seating grooves 152 to elastically support the top surface of the probe card 10. The upper elastic ball 155 may be formed of an elastic silicon material or a urethane material. The upper seating groove 152 is formed in a hemispherical shape having the same size as the upper elastic ball 155.

Since the spherical upper elastic balls 155 support the top surface of the probe card 10, upward and downward vibrations or impacts of the probe card carrier 100 may be evenly distributed in all directions from the upper elastic balls 155. In addition, since the upper elastic balls 155 of the elastic material are in point contact with the top surface of the probe card 10, the plurality of upper elastic balls 155 may maintain a minimal friction area with the probe card 10, thereby significantly reducing the possibility of damage due to frictional force. In addition, when a slight height deviation occurs in the upper elastic ball 155, the amount of shrinkage of the plurality of upper elastic balls 155 may be slightly changed, and thus the top surface of the probe card 10 may be stably supported. In addition, even if a slight deviation in the height of the upper elastic ball 155 occurs, the upper elastic ball 155 may be prevented from being spaced apart from the top surface of the probe card 10.

A fastening protrusion 156 is formed in the upper elastic ball 155, and the upper fastening hole 153 is formed in the upper seating groove 152 so that the fastening protrusion 156 is inserted and restrained. A locking protrusion larger than the upper fastening hole 153 is formed at the end portion of the fastening protrusion 156. Accordingly, it is possible to prevent the upper elastic ball 155 from falling out of the upper seating groove 152.

As described above, the disclosure has been described with reference to the illustrated drawings, but the disclosure is not limited by the embodiments and drawings disclosed herein, and it is apparent that various modifications may be made by those skilled in the art within the scope of the disclosure. In addition, although the above-described embodiments of the disclosure have not been explicitly described and described, it is natural that a predictable effect should also be recognized by the corresponding configuration.

What is claimed is:

1. A probe card carrier comprising:
a lower case;
an upper case configured to cover the lower case;
a seating module disposed in the lower case to allow a probe card to be seated thereon; and
a card buffer portion installed in the seating module to elastically support a bottom surface and a circumference of the probe card.

2. The probe card carrier of claim 1, wherein the card buffer portion includes: a plurality of lower elastic balls disposed in the seating module to elastically support the bottom surface of the probe card, and a plurality of circumferential elastic balls disposed in the seating module to elastically support the circumference of the probe card.

3. The probe card carrier of claim 2, wherein the plurality of lower elastic balls are arranged in the seating module along a circumferential direction.

4. The probe card carrier of claim 2, wherein the plurality of circumferential elastic balls are arranged concentrically with the lower elastic balls on the outside of the plurality of lower elastic balls.

5. The probe card carrier of claim 1, wherein the seating module includes a plurality of seating blocks arranged along the circumferential direction in the lower case, and in which the lower elastic ball and the circumferential elastic ball are arranged.

6. The probe card carrier of claim 5, wherein the seating block includes: a seating plate positioned and fixed to the lower case, a lower supporter protruding upwardly from the seating plate and having a lower seating groove formed in a hemispherical shape to accommodate a bottom side of the lower elastic ball, a circumferential supporter protruding higher than the lower supporter on the outside of the lower supporter and having a circumferential seating groove formed to allow the circumferential elastic ball to protrude toward the lower supporter and to be seated, and a circumferential bracket having a bracket groove formed to surround an upper side of the circumferential elastic ball, and coupled to an upper side of the circumferential supporter.

7. The probe card carrier of claim 5, wherein the seating block is installed to be repositionable in the lower case according to a size or shape of the probe card.

8. The probe card carrier of claim 6, wherein an accommodation space surrounded by the circumferential seating groove and the bracket groove may be formed in a hemispherical shape.

9. The probe card carrier of claim 8, wherein the accommodation space is formed to be larger than half of the circumferential elastic ball to prevent the circumferential elastic ball from falling out of the accommodation space.

10. The probe card carrier of claim 7, wherein a coupling protrusion is formed on the lower elastic ball, and a lower coupling hole is formed in the lower seating groove to allow the coupling protrusion to be inserted and restrained.

11. The probe card carrier of claim 1, further comprising:
a plurality of upper blocks coupled to the upper case and formed with upper seating grooves; and
a plurality of upper elastic balls coupled to the plurality of upper seating grooves to elastically support a top surface of the probe card.

12. The probe card carrier of claim 11, wherein a fastening protrusion is formed on the upper elastic ball, and an upper fastening hole is formed in the upper seating groove to be inserted and restrained the fastening protrusion.

13. The probe card carrier of claim 1, wherein a through-hole portion is formed on the upper case, and further includes a window portion installed to close the through-hole portion, and an upper sealing portion interposed between a circumference of the through-hole portion and a circumference of the window portion.

14. The probe card carrier of claim 1, further comprising:
a sealing member installed to seal a circumference of the lower case and the upper case.

15. The probe card carrier of claim 1, further comprising:
a vacuum valve installed in the upper case.

16. The probe card carrier of claim 1, further comprising:
a plurality of external buffer portions coupled to the circumference of the lower case and the upper case.
